(19) United States
(12) Patent Application Publication
(10) Pub. No.: US 2006/0131669 A1
(43) Pub. Date: Jun. 22, 2006

(54) Thin film transistor for imaging system

(76) Inventors: Douglas Albagli, Clifton Park, NY (US); William Andrew Hennessy, Schenectady, NY (US); Aaron Judy Couture, Schenectady, NY (US); Christopher Collazo-Davila, Clifton Park, NY (US)

Correspondence Address: Patrick S. Yoder;FLETCHER YODER, P.O. Box 692289, Houston, TX, 77269-2289, US

(21) Appl. No.: 11/021,526

(22) Filed: Dec. 22, 2004

(51) Int. Cl. H01L 31/062

(52) U.S. Cl. 257/401

(57) ABSTRACT

An annular thin film transistor includes an annular source electrode disposed above the layer of the semiconductor material, a drain electrode disposed above the layer of the semiconductor material within the annular source electrode, and an active channel between the drain electrode and the annular source electrode, wherein a surface of the active channel comprises exposed semiconductor material. Further, a serpentine thin film transistor includes a serpentine source electrode disposed above the layer of the semiconductor material, a drain electrode disposed above the layer of semiconductor material and substantially within a recess formed by the serpentine source electrode, wherein the drain electrode is configured to substantially conform to the recess, and an active channel between the drain electrode and the serpentine source electrode, wherein the active channel has a substantially consistent length, and wherein a surface of the active channel comprises exposed semiconductor material.

### BACKGROUND

The invention relates generally to imaging systems. In particular, the invention relates to thin film transistors for use in detectors of such imaging systems.

Non-invasive imaging broadly encompasses techniques for generating images of the internal structures or regions of a person or object that are otherwise inaccessible for visual inspection. For example, non-invasive imaging techniques are commonly used in the industrial field for inspecting the internal structures of parts and in the security field for inspecting the contents of packages, clothing, and so forth. One of the best known uses of non-invasive imaging, however, is in the medical arts where these techniques are used to generate images of organs and/or bones inside a patient which would otherwise not be visible.

One class of non-invasive imaging techniques that may be used in these various fields is based on the differential transmission of X-rays through a patient or object. In the medical context, a simple X-ray imaging technique may involve generating X-rays using an X-ray tube or other source and directing the X-rays through an imaging volume in which the part of the patient to be imaged is located. As the X-rays pass through the patient, the X-rays are attenuated based on the composition of the tissue they pass through. The attenuated X-rays then impact a detector that converts the X-rays into signals that can be processed to generate an image of the part of the patient through which the X-rays passed based on the attenuation of the X-rays. Typically the X-ray detection process utilizes a scintillator, which generates optical photons when impacted by X-rays, and an array of photosensor elements, which generate electrical signals based on the number of optical photons detected.

Some X-ray techniques utilize very low energy X-rays so that patient exposure can be extended. For example, fluoroscopic techniques are commonly used to monitor an ongoing procedure or condition, such as the insertion of a catheter or probe into the circulatory system of a patient. Such fluoroscopic techniques typically obtain large numbers of low energy images that can be consecutively displayed to show motion in the imaged area in real-time or near real-time.

However fluoroscopic techniques, as well as other low energy imaging techniques, may suffer from poor image quality due to the relatively weak X-ray signal relative to the electronic noise attributable to the detector. As a result it is typically desirable to improve the efficiency of the detection process, such as by reducing the electronic noise of the detector while in operation. Various aspects of the thin film transistors (TFTs) employed in the detector may contribute to the overall electronic noise. For example, the capacitance between the drain electrode and gate electrode of the TFT is a major component of the overall capacitance of the data line. This in turn, leads to two major noise sources associated with the data line, namely the Johnson noise associated with the resistance of the data line and the noise associated with the read out electronics. Further, the charge trapping currents in TFTs also contribute to the overall electronic noise.

Therefore, there is a need for reducing the electronic noise generated by electronic components in the detector.

### BRIEF DESCRIPTION

In one aspect of the present technique, an X-ray imaging system is provided, where the X-ray imaging system includes an X-ray source configured to emit X-rays and, a detector. The detector includes an array of detector elements, where each detector element comprises a thin film transistor configured for use as a switch. The thin film transistor comprises a drain electrode and a source electrode that are not symmetric to one another. Also provided with the X-ray imaging system is a detection acquisition circuitry configured to acquire the electrical signals, a system controller configured to control at least one of the X-ray source or the detector acquisition circuitry, and an image processing circuitry configured to process the electrical signals to generate an image.

In another aspect of the present technique, an annular thin film transistor is provided, where the annular thin film transistor includes a layer of a semiconductor material, an annular source electrode disposed above the layer of the semiconductor material, a drain electrode disposed above the layer of the semiconductor material within the annular source electrode, and an active channel between the drain electrode and the annular source electrode, wherein a surface of the active channel comprises exposed semiconductor material.

In yet another aspect of the present technique, a serpentine thin film transistor includes a layer of a semiconductor material, a serpentine source electrode disposed above the layer of the semiconductor material, a drain electrode disposed above the layer of semiconductor material and substantially within a recess formed by the serpentine source electrode, wherein the drain electrode is configured to substantially conform to the recess, and an active channel between the drain electrode and the serpentine source electrode, wherein the active channel has a substantially consistent length, and wherein a surface of the active channel comprises exposed semiconductor material.

In still another aspect of the present technique, a method of manufacturing a detector for use in an imaging system is provided. The method includes forming an array of detector elements, where each detector element comprises a thin film transistor.

In another aspect of the present technique, a method of manufacturing an annular thin film transistor is provided. The method includes forming a layer of a semiconductor material, forming an annular source electrode disposed above the layer of the semiconductor material, forming a drain electrode disposed above the layer of the semiconductor material within the annular source electrode, and forming an active channel between the drain electrode and the annular source electrode.

In yet another aspect of the present technique, a method of manufacturing a serpentine thin film transistor includes forming a layer of a semiconductor material, forming a serpentine source electrode disposed above the layer of the semiconductor material, forming a drain electrode disposed above the layer of semiconductor material and substantially within a recess formed by the serpentine source electrode, and forming an active channel between the drain electrode and the serpentine source electrode.

### DRAWINGS

These and other features, aspects, and advantages of the present invention will become better understood when the following detailed description is read with reference to the accompanying drawings in which like characters represent like parts throughout the drawings, wherein:

FIG. 1 is a diagrammatic representation of an exemplary X-ray imaging system, in accordance with one aspect of the present invention;

FIG. 2 is a cut-away perspective view of a detector, in accordance with one aspect of the present invention;

FIG. 3 is a cut away perspective view of an annular thin film transistor, in accordance with one aspect of the present invention;

FIG. 4 is a side view of the annular thin film transistor, in accordance with one aspect of the present invention;

FIG. 5 is a cut away perspective view of a serpentine thin film transistor, in accordance with another aspect of the present invention; and

FIG. 6 is a side view of the serpentine thin film transistor, in accordance with another aspect of the present invention.

### DETAILED DESCRIPTION

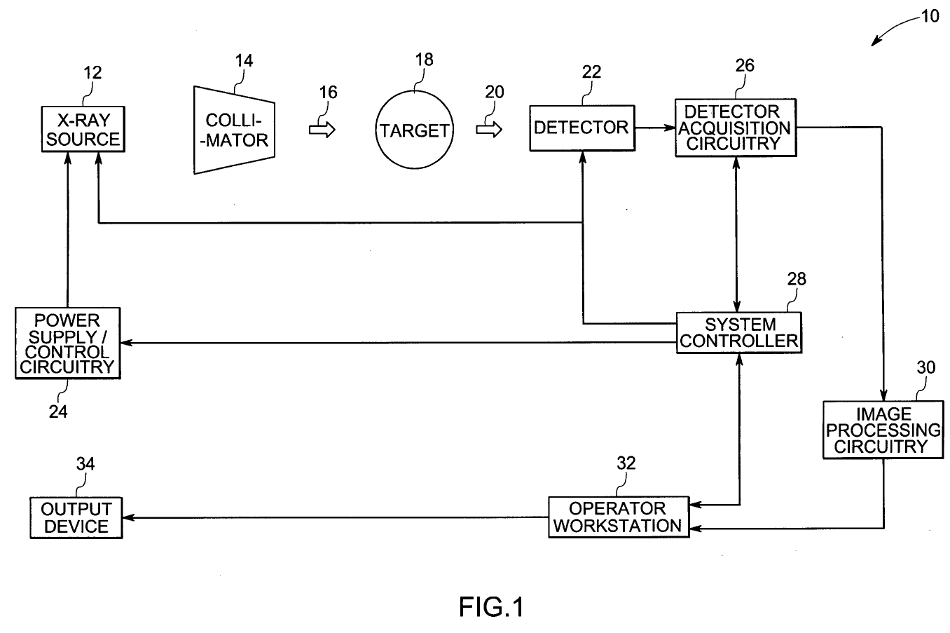

FIG. 1 is an illustration of an X-ray imaging system designated generally by a reference numeral 10. In the illustrated embodiment, the X-ray imaging system 10 is designed to acquire and process image data in accordance with the present technique, as will be described in greater detail below. The X-ray imaging system 10 includes an X-ray source 12 positioned adjacent to a collimator 14. In one embodiment, the X-ray source 12 is a low-energy source and is employed in low energy imaging techniques, such as fluoroscopic techniques, or the like. Collimator 14 permits a stream of X-ray radiation 16 to pass into a region in which a target 18, such as a human patient, is positioned. A portion of the radiation is attenuated by the target 18. This attenuated radiation 20 impacts a detector 22, such as a fluoroscopic detector. As will be appreciated by one of ordinary skill in the art, the detector 22 may be based on scintillation, i.e., optical conversion, on direct conversion, or on other techniques used in the generation of electrical signals based on incident radiation. For example, a scintillator-based detector converts X-ray photons incident on its surface to optical photons, these optical photons may then be converted to electrical signals by employing photodiodes. Conversely, a direct conversion detector directly generates electrical charges in response to X-ray's and the electrical signals are stored and read out from storage capacitors. As described in detail below, these electrical signals, regardless of the conversion technique employed are acquired and processed to construct an image of the features within the target 18.

The X-ray source 12 is controlled by power supply/control circuitry 24 which furnishes both power and control signals for examination sequences. Moreover, detector 22 is coupled to detector acquisition circuitry 26, which commands acquisition of the signals generated in the detector 22. Detector acquisition circuitry 26 may also execute various signal processing and filtration functions, such as, for initial adjustment of dynamic ranges, interleaving of digital, and so forth.

In the depicted exemplary embodiment, one or both of the power supply/control circuitry 24 and detector acquisition circuitry 26 are responsive to signals from a system controller 28. In some exemplary systems it may be desirable to move one or both of the detector 22 or the X-ray source 12. In such systems, a motor subsystem may also be present as a component of the system controller 28 to accomplish this motion. In the present example, the system controller 28 also includes signal processing circuitry, typically based upon a general purpose or application specific digital computer. The system controller 28 may also include memory circuitry for storing programs and routines executed by the computer, as well as configuration parameters and image data, interface circuits, and so forth.

Image processing circuitry 30 is also present in the depicted embodiment of the X-ray imaging system 10. The image processing circuitry 30 receives acquired projection data from the detector acquisition circuitry 26 and processes the acquired data to generate one or more images based on X-ray attenuation.

One or more operator workstation 32 is also present in the depicted embodiment of the X-ray imaging system 10. The operator workstation 32 allows an operator to initiate and configure an X-ray imaging examination and to view the images generated as part of the examination. For example, the system controller 28 is generally linked to operator workstation 32 so that an operator, via one or more input devices associated with the operator workstation 32, may provide instructions or commands to the system controller 28.

Similarly, the image processing circuitry 30 is linked to the operator workstation 32 such that the operator workstation 32 may receive and display the output of the image processing circuitry 30 on an output device 34, such as a display or printer. The output device 34 may include standard or special purpose computer monitors and associated processing circuitry. In genetal, displays, printers, operator workstations, and similar devices supplied within the system may be local to the data acquisition components or may be remote from these components, such as elsewhere within an institution or hospital or in an entirely different location. Output devices and operator workstations that are remote from the data acquisition components may be linked to the image acquisition system via one or more configurable networks, such as the internet, virtual private networks, and so forth. As will be appreciated by one of ordinary skill in the art, though the system controller 28, image processing circuitry 30, and operator workstation 32 are shown distinct from one another in FIG. 1, these components may actually be embodied in a single processor-based system, such as a general purpose or application specific digital computer. Alternatively, some or all of these components may be present in distinct processor-based systems, such as a general purpose or application specific digital computers, configured to communicate with one another. For example, the image processing circuitry 30 may be a component of a distinct reconstruction and viewing workstation.

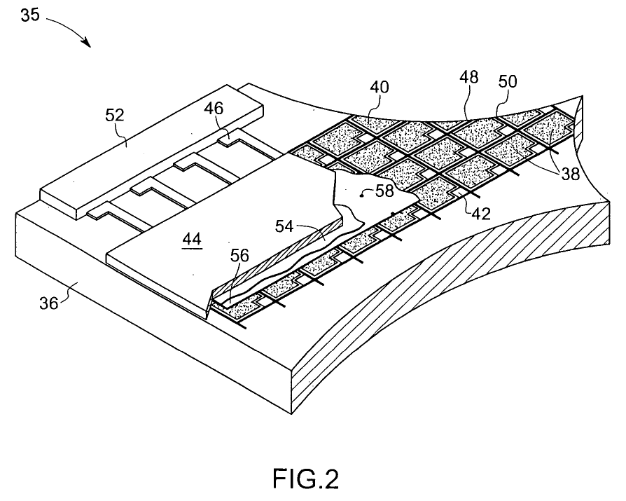

Referring now to FIG. 2, a scintillation-based detector 35 introduced in FIG. 1 is discussed in greater detail. Though the scintillation-based detector 35 of FIG. 2 is discussed herein as an example for use with the present technique, it should be remembered that this is only one example. Other detectors 22, such as direct conversion detectors, may also benefit from the present technique in the manner described herein. Discussion of the scintillation-based detector 35, therefore, should be understood to be merely exemplary and presented for the purpose of illustrating the principles of operation for one type of detector which may benefit from the present technique.

Turning now to FIG. 2, an exemplary physical arrangement of the components of a scintillation-based detector 35 is presented in accordance with one embodiment of the present invention. The detector 22 typically includes a glass substrate 36 on which the components described below are disposed. In the depicted embodiment, the scintillation-based detector 35 includes an array of photosensor elements 38. In one implementation, the photosensor elements 38 are photodiodes formed from silicon. In the exemplary embodiment of FIG. 2, the photodiodes are arranged in an array of rows and columns that define the pixels, or picture elements, read out by the detector acquisition circuitry 26. Each photodiode includes a photosensitive region 40, and a thin film transistor (TFT) 42, which may be selectively activated using data lines 48 and scan lines 50.

Further, the scintillation-based detector 35 includes a scintillator 44, which, when exposed to X-rays, generates the optical photons detected by the photosensitive regions 40. As illustrated in this embodiment, a conductive layer 54 disposed on a dielectric layer 56 is disposed between the scintillator 44 and the array of photosensor elements 38. Vias 58 electrically couple the conductive layer 54 to the top surface of each element of the array of photosensor elements 38 to allow a common bias to be applied to each photosensor element.

In embodiments employing a direct conversion detector, as opposed to a scintillation-based detector 35 discussed above, a photoconductor (such as of selenium, lead oxide, lead iodide, mercuric iodide, and so forth) is utilized in place of the scintillator. Similarly, simple storage capacitors are utilized in place of the photosensitive diodes in such a direct conversion detector. Other aspects of such a direct-conversion detector, including the use of data and scan lines, vias and bridges, and the use of TFTs 42, are similar or analogous to scintillation-based detector 35 described above and, therefore, may also benefit from the present technique as described herein.

In accordance with the present invention, and as discussed in greater detail below, the TFTs include a source electrode and a drain electrode that are not symmetric to one other. In certain embodiments, the drain electrode is smaller that the source electrode. This asymmetry allows a reduction in drain-to-gate capacitance, particularly relative to the source-to-gate capacitance, to the extent that these capacitances are a function of the overlap of the gate electrode with each of the drain and source electrodes, respectively. As will be appreciated by those skilled in the art, reducing the drain-to-gate capacitance generally reduces the noise associated with the TFT, thereby increasing the signal-to-noise ratio (SNR).

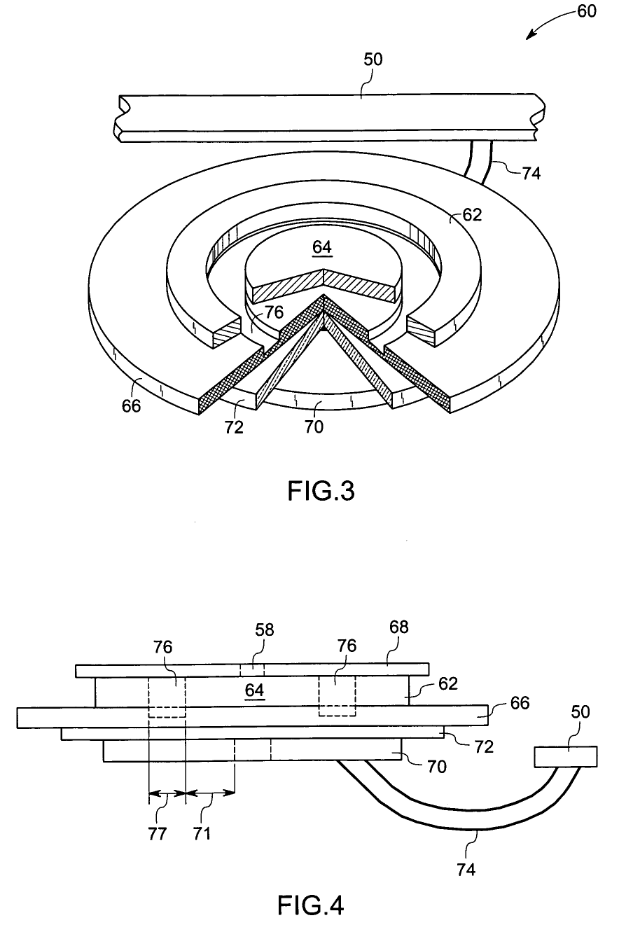

For example, in one embodiment, the TFT 42 is a structure in which the source electrode partially or completely encloses the drain electrode. For simplicity, such a structure will be referred to as an annular TFT 60 herein, though, as will be appreciated by those skilled in the art, the annular source electrode 62 may be any enclosing shape such as, oval, rectangular, square, etc., as opposed to circular. Similarly, the enclosed drain electrode 64 may be other shapes than circular. For simplicity, however, the annular TFT 60 described herein, and depicted in FIGS. 3 and 4, is circular.

Referring now to FIGS. 3, an annular TFT 60 is depicted which includes an annular source electrode 62. A disc-shaped drain electrode 64 is depicted as disposed within the annular source electrode 62. Both, the annular source electrode 62 and the drain electrode 64 are disposed above a layer 66 of a semiconductor material, such as, silicon.

The annular TFT 60 is coupled to vertically offset data lines (not shown) by electrically conductive vias 58, such as shown with respect to the disc-shaped drain electrode 64 in FIG. 4. Typically, vias 58 pass through a TFT passivation dielectric layer 68 and the dielectric layer 56 (see FIG. 2) disposed above the array of photosensor elements 38 and TFTs 42, to contact a landing pad on the disc-shaped drain electrode 64 to a data line. The TFT passivation dielectric layer 68 is typically deposited over the TFT so as to passivate the semiconductor surface of the layer 66 and also to isolate the source and drain electrodes 62 and 64 from subsequent depositions.

In the illustrated embodiment of FIG. 3, a gate electrode 70 is disposed beneath the semiconductor layer 66. In one embodiment, the gate electrode 70 is annular so as to minimize the drain-to-gate overlap 71 (FIG. 4) and therefore, reduce the drain-to-gate capacitance. In one embodiment, the drain-to-gate overlap 71 is up to about 4 microns. In another embodiment, there is substantially no drain-to-gate overlap. In the depicted embodiment, a dielectric layer 72 is disposed between the gate electrode 70 and the semiconductor layer 66. The gate electrode 70 is coupled to a scan line 50 via bridge 74 to allow proper operation of the TFT.

Further, in the depicted embodiment of FIG. 4, the annular source electrode 62 and the drain electrode 64 are separated by an active channel 76. The bottom surface of the active channel 76 typically comprises exposed semiconductor material of the semiconductor layer 66. The active channel 76 is typically formed by partially etching, the semiconductor layer 66. In the illustrated embodiment, total distance traversed by the active channel 76 parallel to the source and drain electrodes 62 and 64 represents the width of the active channel 76. In one embodiment, the width of the active channel 76 is in a range from about 15 microns to about 150 microns. In the depicted embodiment, the active channel has a substantially consistent length 77, where the length 77 is a perpendicular distance between the source and drain electrodes 62 and 64. In one embodiment, the length 77 may be any single value between 1 micron and 5 microns, though in other embodiments the length 77 may be other values. Also, due to the geometry of the annular source electrode 62 and the drain electrode 64 in the annular TFT 60, the active channel does not include any entrance or exit. As a result, all the exposed semiconductor material of the layer 66 is part of the active channel 76. In addition, in the illustrated embodiment, there is less charge retention and also, less drain-to-gate capacitance, which in turn, minimizes the noise associated with the on resistance of the channel. Furthermore, the drain-to-gate overlap 71 of the depicted embodiment is tolerant to misalignment between the gate electrode 70 and the annular source electrode 62 and the drain electrode 64.

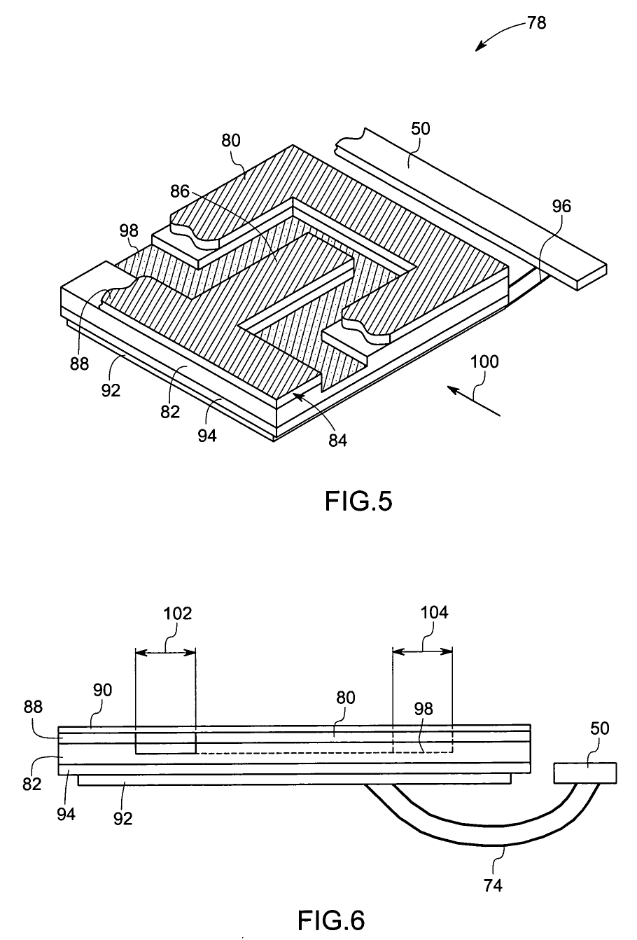

In another embodiment, the TFT 42 is a structure in which the source electrode and drain electrode are differently sized. In such an embodiment, the source and drain electrodes may also be interleaved. For simplicity, such a structure will be referred to as a serpentine TFT 78 herein. For example, referring now to FIGS. 5 and 6, FIG. 5 illustrates a perspective view of a serpentine TFT 78 employed in the detector 22 according to one aspect of the present technique. FIG. 6 illustrates a side view of the serpentine TFT 78 taken from the direction represented by reference numeral 100 as shown in FIG. 5. In the illustrated embodiment of FIG. 6, the TFT passivation dielectric layer 90 is disposed above the serpentine TFT 78. In one embodiment, the serpentine TFT 78 includes a serpentine source electrode 80 disposed on a semiconductive layer 82 of a semiconductor material, such as silicon. In certain embodiments, the serpentine source electrode 80 comprises a U-shaped source electrode. In the illustrated embodiment, the serpentine TFT 78 further comprises a drain electrode 84 disposed above the semiconductive layer 82 and shaped to generally conform to and interleave with the source electrode 80. In the depicted embodiment, the drain electrode 84 is generally T-shaped, such that the base 86 of the T-shape is interleaved with the source electrode 80. This design of the drain electrode 84 provides reduced surface area, i.e., a narrow drain electrode, relative to the area of the serpentine thin film transistor 78, and avoids process related defects associated with a narrow drain electrode passing over the gate electrode 92. In such an embodiment, the drain-to-gate capacitance is reduced relative to the source-to-gate capacitance as compared to a TFT having a similarly sized source and drain. As a result, in operation the serpentine TFT 78 generates less noise than a TFT having a similarly sized, i.e., symmetric, source and drain. In one embodiment, the length of the drain base 86 is in a range from about 1 micron to about 3 microns. In the illustrated embodiment, the drain electrode 84 is electrically coupled to the data lines 48 such as by a bridge and a via (not shown). Further, a dielectric layer 94 is typically disposed between the gate electrode 92 and the semiconductive layer 82. The gate electrode 92 is electrically coupled to a scan line 50 by a bridge 96 (as depicted in FIG. 5) or a via depending on how the scan line 50 and gate electrode 92 are offset.

In addition, as will be appreciated by those of ordinary skill in the art, the source electrode 80 and the drain electrode 84 are separated by an active channel 98, typically formed by etching a portion of the semiconductive layer 82. As will be appreciated by those of ordinary skill in the art, the active channel 98 has a width, where the width is a distance traversed by the active channel 98 in a direction parallel to the source and drain electrodes 80 and 84. In one embodiment, the width of the active channel 98 is in a range from about 15 microns to about 150 microns. In the illustrated embodiment of FIG. 6, the active channel 98 has a substantially consistent length, where the length is a perpendicular distance between the source and drain electrodes 80 and 84. As depicted, the active channel 98 has a length represented by reference numerals 102 and 104. In this embodiment, the active channel 98 is any single value between 1 micron and 5 microns. As noted above, the substantially consistent length of the active channel results in the exposed semiconductor material of the semiconductive layer 82 being part of the active channel 98.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An X-ray imaging system comprising:
an X-ray source configured to emit X-rays;
a detector configured to generate electrical signals in response to incident X-rays; comprising:
an array of detector elements, each detector element comprising a thin film transistor configured for use as a switch and wherein a drain electrode and a source electrode of the thin film transistor are not symmetric to one another;
detector acquisition circuitry configured to acquire the electrical signals;
a system controller configured to control at least one of the X-ray source or the detector acquisition circuitry; and
an image processing circuitry configured to process the electrical signals to generate an image.

2. The X-ray imaging system of claim 1, wherein each detector element comprises:
a scintillator configured to emit optical photons in response to X-rays; and
a photosensor element configured to generate electrical signals in response to the optical photons.

3. The X-ray imaging system of claim 1, wherein the detector comprises:
a photoconductor element configured to generate electrons in response to X-rays; and
a storage capacitor configured to generate electrical signals in response to the electrons generated by the photoconductor.

4. The X-ray imaging system of claim 1, wherein the drain electrode is smaller than the source electrode.

5. The X-ray imaging system of claim 1, wherein the X-ray source comprises a low-energy X-ray source.

6. The X-ray imaging system of claim 1, wherein the detector comprises a fluoroscopic detector.

7. The X-ray imaging system of claim 1, wherein the thin film transistor comprises an annular thin film transistor.

8. The X-ray imaging system of claim 7, wherein the annular thin film transistor comprises:
a layer of a semiconductor material;
an annular source electrode disposed above the layer of the semiconductor material;
a drain electrode disposed above the layer of the semiconductor material within the annular source electrode; and
an active channel between the drain electrode and the annular source electrode, wherein a surface of the active channel comprises exposed semiconductor material.

9. The X-ray imaging system of claim 8, wherein the active channel has a substantially consistent length.

10. The X-ray imaging system of claim 8, wherein the drain electrode is circular.

11. The X-ray imaging system of claim 1, wherein the thin film transistor comprises a serpentine thin film transistor, comprising:
a layer of a semiconductor material;
a serpentine source electrode disposed above the layer of the semiconductor material;
a drain electrode disposed above the layer of semiconductor material and substantially within a recess formed by the serpentine source electrode, wherein the drain electrode is configured to substantially conform to the recess; and
an active channel between the drain electrode and the serpentine source electrode, wherein the active channel has a substantially consistent length, and wherein a surface of the active channel comprises exposed semiconductor material.

12. The X-ray imaging system of claim 11, wherein the serpentine source electrode comprises a U-shaped source electrode.

13. An annular thin film transistor comprising:
a layer of a semiconductor material;
an annular source electrode disposed above the layer of the semiconductor material;
a drain electrode disposed above the layer of the semiconductor material within the annular source electrode; and
an active channel between the drain electrode and the annular source electrode, wherein a surface of the active channel comprises exposed semiconductor material.

14. The annular thin film transistor of claim 13, wherein the active channel has a substantially consistent length.

15. The annular thin film transistor of claim 14, wherein the length is in a range from about 1 micron to about 5 microns.

16. The annular thin film transistor of claim 13, wherein the drain electrode is circular.

17. The annular thin film transistor of claim 13, wherein the annular source electrode is oval, rectangular, square, or combinations thereof.

18. The annular thin film transistor of claim 13, wherein the active channel is substantially free of exposed semiconductor material that is not part of the active channel.

19. A serpentine thin film transistor comprising:
a layer of a semiconductor material;
a serpentine source electrode disposed above the layer of the semiconductor material;
a drain electrode disposed above the layer of semiconductor material and substantially within a recess formed by the serpentine source electrode, wherein the drain electrode is configured to substantially conform to the recess; and
an active channel between the drain electrode and the serpentine source electrode, wherein the active channel has a substantially consistent length, and wherein a surface of the active channel comprises exposed semiconductor material.

20. The serpentine thin film transistor of claim 19, wherein the length is in a range from about 1 micron to about 5 microns.

21. The serpentine thin film transistor of claim 19, wherein a length of the drain electrode is in a range from about 1 micron to about 3 microns.

22-24. (canceled)
